(19) United States
(12) Patent Application Publication
(10) Pub. No.: US 2026/0096495 A1
(43) Pub. Date: Apr. 2, 2026

(54) MICROELECTRONIC ASSEMBLY WITH INTEGRATED PASSIVE COMPONENT AND SEMICONDUCTOR DEVICE

(71) Applicant: Texas Instruments Incorporated, Dallas, TX (US)

(72) Inventors: John Carlo Molina, Limay (PH); Omar Humberto Maynes Diaz, Aguascalientes (MX); Nicole Yabuuchi, Pampanga (PH)

(21) Appl. No.: 18/902,490

(22) Filed: Sep. 30, 2024

(51) Int. Cl. H01L 23/498; H01L 21/48; H01L 21/56; H01L 23/00; H01L 23/31; H01L 25/16

(52) U.S. Cl. CPC H10W 90/701; H10D 1/20; H10W 70/093; H10W 74/01; H10W 74/131; H10W 90/00; H10W 90/794

(57) ABSTRACT

An example apparatus includes: conductive stud bumps on a device side surface of a multilayer circuit substrate arranged to mount a passive component; at least one semiconductor die flip-chip mounted to the device side surface of the multilayer circuit substrate, the at least one semiconductor die having bond pads coupled to conductors in the multilayer circuit substrate; mold compound deposited over the device side surface of the multilayer circuit substrate, the mold compound covering a portion of the semiconductor die and having a trench extending into the mold compound that exposes the conductive stud bumps; and a passive component mounted to the conductive stud bumps, the passive component having terminals that extend into the trenches in the mold compound and contact a surface of the conductive stud bumps.

### TECHNICAL FIELD

This disclosure relates generally to electronic packaging, and more particularly to packaging semiconductor devices and associated passive components in a microelectronic assembly.

### BACKGROUND

The semiconductor industry continually develops packaged devices with more functionality by placing components in a single packaged device such as a module. By providing a semiconductor die or multiple semiconductor die devices and by including the necessary passive components and semiconductor dies to form a commonly needed function in a single microelectronic assembly, users of the assembly are freed from the necessity of determining the values and types of various passive components needed with a semiconductor die to perform these common functions. By integrating these devices into a single microelectronic assembly, the system board area needed to implement the function is reduced. Examples microelectronic assemblies include power supplies, power converters, voltage regulators, battery chargers, and power controllers. A power module may include a power semiconductor die, such as a switching power controller and a power transistor or may include a power transistor gate driver, along with various passive components such as capacitors, resistors, and inductors to form a complete power system.

The passive components used in these modules can include relatively large inductors, coils, or transformers as passive components. These passive components can be mounted near the semiconductor die on a circuit substrate, and traces on the circuit substrate can couple the devices together. One example application for an integrated passive component is a power module inductor, which can be coupled between a switching node and a load, for example. A switching power semiconductor die can alternatively supply current to or sink current from the inductor to provide a function, such as a regulated output voltage for a load. The switching power semiconductor die can include power transistors for supplying current from a voltage supply and gate driver transistors for controlling the operation of the power transistors. By operating the power transistors using frequency modulation, a regulated voltage can be output using the inductor. Transformers can be formed from inductors coupled to multiple power semiconductor dies. Transformers can couple current across an isolation barrier, to provide current to a load isolated from a power supply, for example.

To assemble the semiconductor dies and the inductors in a module or microelectronic assembly, the semiconductor dies cam be mounted to a circuit substrate. To mount the inductors to the circuit substrate, conductive clips have been mounted to the substrate, and subsequently, the inductors have been mounted to the conductive clips. Assembly of a module using the semiconductor dies and the clips requires multiple mounting steps. Molding operations performed to protect the semiconductor dies can be impacted by the clips creating coplanarity issues. The assembly process that uses the clips to mount inductors with semiconductor dies is costly and complex.

There is a continuing need for increasingly reliable and cost-effective assembly methods providing passive components with semiconductor dies in a microelectronic device assembly.

### SUMMARY

In a described example, a method includes: forming conductive stud bumps on a device side surface of a multilayer circuit substrate arranged to mount a passive component; flip chip mounting at least one semiconductor die on the device side surface of the multilayer circuit substrate, the flip chip mounted semiconductor die having bond pads coupled to conductors in the multilayer circuit substrate; depositing mold compound over the device side surface of the multilayer circuit substrate, the mold compound covering the conductive stud bumps and portions of the flip chip mounted semiconductor die, a backside surface of the semiconductor die exposed from the mold compound; cutting trenches in the mold compound over the conductive stud bumps to form trenches in the mold compound, the conductive stud bumps having a surface exposed within the trenches in the mold compound; and mounting a passive component to the conductive stud bumps, the passive component having terminals that extend into the trenches in the mold compound and contact the exposed surface of the conductive stud bumps.

In another described example, an apparatus includes: conductive stud bumps on a device side surface of a multilayer circuit substrate arranged to mount a passive component; at least one semiconductor die flip-chip mounted to the device side surface of the multilayer circuit substrate, the at least one semiconductor die having bond pads coupled to conductors in the multilayer circuit substrate; mold compound deposited over the device side surface of the multilayer circuit substrate, the mold compound covering a portion of the semiconductor die and having a trench extending into the mold compound that exposes the conductive stud bumps; a passive component mounted to the conductive stud bumps, the passive component having terminals that extend into the trenches in the mold compound and contact a surface of the conductive stud bumps.

In a further described example, a microelectronic assembly includes: a multilayer circuit substrate having conductive stud bumps on a device side surface arranged to mount a passive component; at least one semiconductor die flip-chip mounted to the device side surface of the circuit substrate, a first one of the conductive stud bumps spaced from a first end of the semiconductor die, and a second one of the conductive stud bumps spaced from a second end of the semiconductor die; mold compound deposited over a portion of the at least one semiconductor die, and trenches in the mold compound exposing a surface of the conductive stud bumps, the at least one semiconductor die having a backside surface exposed from the mold compound; and a passive component having terminals mounted to the conductive stud bumps, the passive component positioned over a portion of a backside surface of the at least one semiconductor die.

### BRIEF DESCRIPTION OF THE DRAWINGS

FIGS. 1A-1B are cross-sectional drawings of a multilayer circuit substrate and of a semiconductor die mounted to a multilayer circuit substrate, components useful in with the arrangements.

FIGS. 2A-2B are perspective views of the components of the apparatus of FIGS. 1A-1B.

FIGS. 3A and 3B illustrate in two projection views a semiconductor wafer having semiconductor devices formed on it and configured for flip-chip mounting, and an individual semiconductor die for flip-chip mounting, respectively.

FIG. 4 illustrates in a cross-sectional view an example multilayer circuit substrate that can be used in an arrangement.

FIGS. 5A-5B illustrate, in a series of cross-sectional views, selected steps for a method for forming a multilayer circuit substrate that is useful with the arrangements.

FIG. 6A illustrates, in a cross-sectional view, an example arrangement with a passive component and a semiconductor die in a microelectronic assembly. FIG. 6B illustrates in a cross-sectional view, a multilayer circuit substrate with conductive stud bumps formed on a device side surface. FIG. 6C-6G illustrate, in a series of steps, a method for mounting a semiconductor die and a passive component to a circuit substrate to form the arrangement of FIG. 6A,

FIG. 7 illustrates, in a projection view, a microelectronic assembly using an example arrangement to mount passive components and semiconductor dies to a circuit substrate.

FIG. 8 illustrates in a flow diagram an example method for forming an arrangement.

### DETAILED DESCRIPTION

In the drawings, corresponding numerals and symbols generally refer to corresponding parts unless otherwise indicated. The drawings are not necessarily drawn to scale.

Elements are described herein as “coupled.” The term “coupled” includes elements that are directly connected and elements that are indirectly connected, and elements that are electrically connected even with intervening elements or wires are coupled.

The term “semiconductor die” is used herein. A semiconductor die can be a discrete semiconductor device such as a bipolar transistor, a few discrete devices such as a pair of power field effect transistor (“FET”) switches fabricated together on a single semiconductor die, or a semiconductor die can be an integrated circuit with multiple semiconductor devices such as the multiple capacitors in an A/D converter. The semiconductor die can include passive devices such as resistors, inductors, filters, sensors, or active devices such as transistors. The semiconductor die can be an integrated circuit with hundreds or thousands of transistors coupled to form a functional circuit, for example a microprocessor or memory device.

The term “passive component” is used herein. A passive component is a component without a transistor device, examples include inductors, coils, transformers, capacitors, resistors, diodes, and sensors. For example, a passive component can be an inductor. Inductors useful in the arrangements can be two terminal inductors with thermal bands to enhance thermal dissipation. Other passive components including resistors, coils, inductors, diodes, and sensors can be formed as passive component dies and can be used in the arrangements. By providing the passive components needed to form a complete commonly needed function, users of the modules are freed from the need to provide mounting area on a board for the passives and from the need to determine values for the passive components needed to complete the function, that is the modules are increasingly integrated into systems.

In some arrangements, multiple semiconductor dies can be packaged together. For example, a power metal oxide semiconductor (MOS) field effect transistor (FET) semiconductor die, and a logic semiconductor die (such as a gate driver die, or a power FET controller die) can be packaged together. These integrated devices can be referred to as “multichip modules” or “system-in-package” (or “SIP”) devices. In example arrangements, at least one semiconductor die is mounted to a circuit substrate that provides conductive leads; a portion of the conductive leads form the terminals for the module or microelectronic assembly. The semiconductor die can be flip chip mounted to a circuit substrate with a device side surface facing the substrate and a backside surface facing away from the circuit substrate. In flip chip semiconductor device packages, conductive post connects that extend from bond pads on the semiconductor die and have solder deposited on a distal end couple conductive leads of a circuit substrate to bond pads on the semiconductor die. A thermoset epoxy resin can be applied to the semiconductor die in a molding process, or using epoxy, plastics, or resins that are liquid at room temperature and are subsequently cured. The mold compound may be formed in a mold using an encapsulation process.

The term “circuit substrate” is used herein. A circuit substrate is a substrate arranged to receive a semiconductor die and to support the semiconductor die in a completed module or microelectronic assembly. Circuit substrates useful with the arrangements include multilayer substrates. In example multilayer circuit substrates that are useful with the arrangements, build-up circuit substrates can be used. Multilayer circuit substrates have trace level conductors spaced by dielectric material in layers, and vertical connection layers that extend through the dielectric material between trace level conductors to form routing networks. Alternative circuit substrates that can be used include conductive leadframes, which can be formed from copper, aluminum, stainless steel, steel, and alloys such as Alloy 42 and copper alloys. The leadframes can include a die pad with a die side surface for mounting a semiconductor die, and conductive leads arranged near and spaced from the die pad for coupling to bond pads on the semiconductor die. Semiconductor dies can be flip chip mounted to the leadframes using conductive post connects to couple the bond pads of the semiconductor die to conductive lands on the leadframe.

The term “build-up circuit substrate” is used herein. A build-up circuit substrate is a circuit substrate that has multiple trace level conductor layers, and which has vertical connection layers extending through dielectric material between the trace level conductor layers. In an example arrangement, a build-up circuit substrate is formed in an additive process by plating a patterned conductor level and then covering the conductor with a layer of film dielectric material. The film dielectric material can be applied at an elevated temperature to soften the film material, and a vacuum can be used to cause the film dielectric material to conform to the conductors underneath. The film dielectric material can then be thermally cured to harden the dielectric material. Multiple layers of the film dielectric material can be applied. Grinding can be performed on the dielectric material to expose portions of the layer of conductors. Additional plating layers can be formed to add additional levels of conductors, some of which are coupled to the prior trace level conductor layers by vertical connection layers, and additional film dielectric material can be deposited at each level and can cover the conductors. By using an additive or build up manufacturing approach, and by performing multiple plating steps, molding steps, and grinding steps, a build-up circuit substrate can be formed with an arbitrary number of layers. In an example arrangement, copper conductors are formed by plating, and a thermoplastic material can be used as the dielectric material. In a particular example, the dielectric film can be an epoxy-based build-up film commercially available as “Ajinomoto Build-up Film,” from Ajinomoto Co., Inc., of Tokyo, Japan.

In packaging microelectronic and semiconductor devices, mold compound may be used to partially cover a circuit substrate, to cover components, to cover a semiconductor die, and to cover the electrical connections from the semiconductor die to the substrate. This molding process can be referred to as an “encapsulation” process, although some portions of the substrates are not covered in the mold compound during encapsulation, for example terminals and leads of the circuit substrate are exposed from the mold compound. Encapsulation is often a compressive molding process, where thermoset mold compound such as resin epoxy can be used. A room temperature solid or powder mold compound can be heated to a liquid state and then molding can be performed by pressing the liquid mold compound into a mold through runners or channels. Transfer molding can be used. Compression molding can be used, where the units to be covered with mold compound are pressed into a two-part mold with mold compound to force the mold compound to fill the mold. Unit molds shaped to surround an individual device may be used, or block molding may be used, to form multiple packages simultaneously for several devices from mold compound. The devices to be molded can be provided in an array or matrix of several, hundreds or even thousands of devices in rows and columns that are then molded together. When mold compound is formed over the components mounted to a device mounting surface of a circuit substrate, it may be referred to as an “overmolding” process.

After the molding, the individual packaged devices are cut from each other in a sawing operation by cutting through the mold compound and circuit substrate in saw streets formed between the devices. Portions of the circuit substrate leads are exposed from the mold compound package to form terminals for the microelectronic device packages.

The term “scribe lane” is used herein. A scribe lane is a portion of semiconductor wafer between semiconductor dies. Sometimes in related literature the term “scribe street” or “scribe line” is used. Once semiconductor processing is finished and the semiconductor devices are complete, the semiconductor devices are separated into individual semiconductor dies by severing the semiconductor wafer along the scribe lanes. The separated dies can then be removed and handled individually for further processing. This process of removing dies from a wafer is referred to as “singulation” or sometimes referred to as “dicing.” Scribe lanes are arranged on four sides of semiconductor dies and when the dies are singulated from one another, rectangular semiconductor dies are formed.

The term “saw street” is used herein. A saw street is an area between molded electronic devices used to allow a saw, such as a mechanical blade, laser, or other cutting tool to pass between the molded electronic devices to separate the devices from one another. This process is another form of singulation. When the molded electronic devices are provided in a strip with one device adjacent to another device along the strip, the saw streets are parallel and normal to the length of the strip. When the molded electronic devices are provided in an array of devices in rows and columns, the saw streets include two groups of parallel saw streets, the two groups are normal to each other, and the saw will traverse the molded electronic devices in two different directions to cut apart the packaged electronic devices from one another in the array.

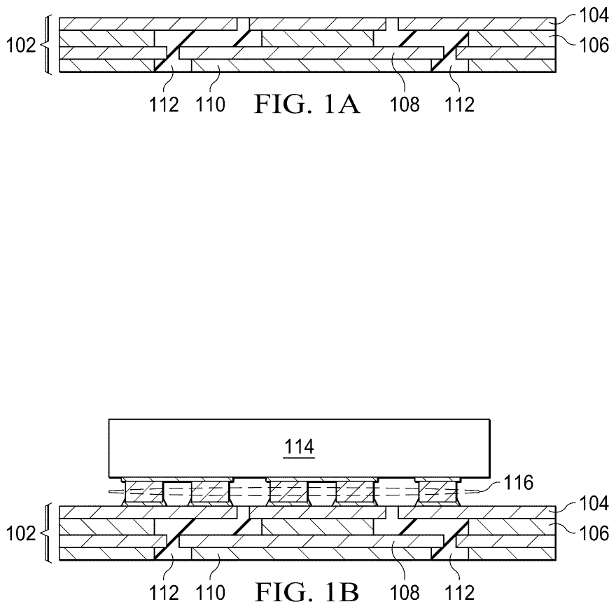

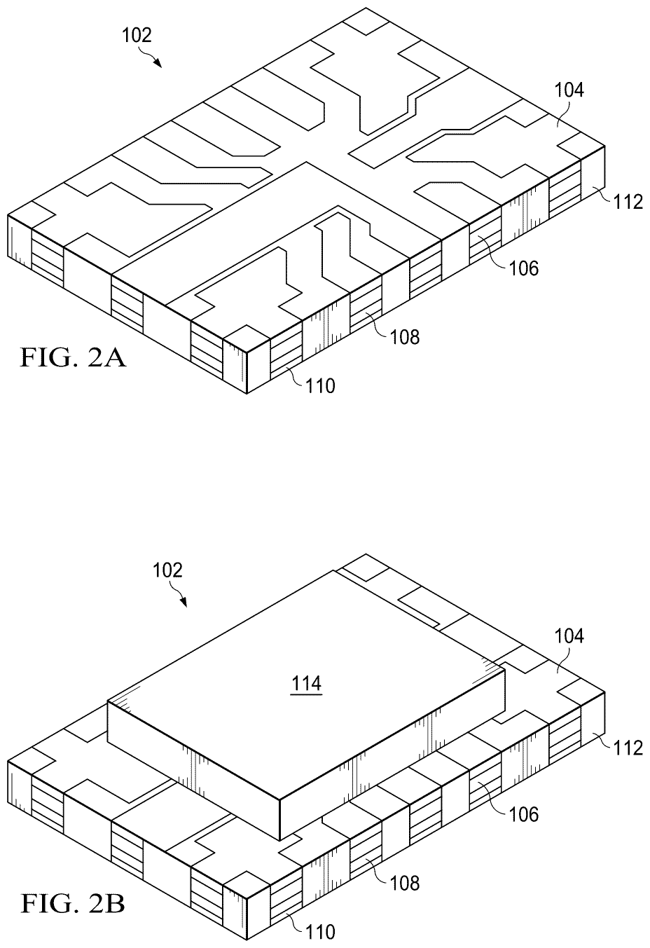

FIGS. 1A-1B are cross-sectional drawings illustrating a circuit substrate, and a semiconductor die flip chip mounted to the circuit substrate. FIGS. 2A-C are perspective diagrams of the components illustrated in FIGS. 1A-1C.

In FIG. 1A, an example circuit substrate 102 includes four layers: first layer 104, second layer 106, third layer 108, and fourth layer 110. Each of these layers can have a patterned conductive layer comprising copper, silver, titanium, gold, or other conductive materials, including alloys of these conductive materials. In this example circuit substrate 102, layer 110 is on the board side of circuit substrate 102, and portions of layer 110 are shaped to form terminals. Layer 104 is on the device mounting surface of circuit substrate 102, and portions of this layer are arranged to form conductive lands for receiving a flip-chip mounted semiconductor die. The portion of each conductive layer 104, 106, 108, 110 that does not include conductive material is filled with dielectric material such as dielectric 112. The dielectric material 112 of circuit substrate 102 can be a thermoplastic or a thermoset material.

In a process useful with the arrangements, the multilayer circuit substrate 102 can be a build-up circuit substrate. Build-up circuit substrates can be formed in an additive manufacturing process by using sputter deposition to deposit a seed layer on a carrier or film, masking the seed layer, plating a conductor layer on the seed layer, removing unwanted portions of the seed layer, and then using an epoxy film to form the dielectric material, this process is performed repeatedly in laminated layers. An example film used in forming build-up circuit substrates is Ajinomoto Build-Up Film (ABF). By using an additive process to form the build-up circuit substrate in layers, and in contrast to laminated substrates formed with vias between trace layers, arbitrary conductor shapes can be formed including rails or other rectangular shapes as vertical connection layers between the trace level conductors. By forming conductor shapes vertically using the ABF lamination process, the conductors can be stacked to form columns, blocks, or rails of various thicknesses to form low resistance paths between devices on the device side surface of the circuit substrate and terminals on a board side surface. Alternative dielectric materials include thermoplastics such as ASA (Acrylonitrile Styrene Acrylate), thermoset mold compound including epoxy resin, epoxies, resins, or plastics. A perspective view of circuit substrate 102 is shown in FIG. 2A.

FIG. 1B shows an example semiconductor die 114 that is flip chip mounted on circuit substrate 102. Semiconductor die 114 includes conductive post connects 116. Conductive post connects 116 are formed on bond pads (not shown in this figure) on the surface of semiconductor die 114. A solder bump (not shown in this figure) can be formed on top of each of the distal ends of the conductive post connects. The semiconductor die is then flipped over so that the device side surface faces the device mounting surface of the circuit substrate, and the semiconductor die positioned so that the solder bumps contact pads in layer 104. Compression, heat, or vibration is used to form a conductive connection from layer 104 to conductive post connects 116 via the solder bumps. A perspective view of semiconductor die 114 mounted on circuit substrate 102 is shown in FIG. 2B.

FIGS. 1A-1B and 2A-2B illustrate certain details of flip chip semiconductor die mounts using circuit substrates. Not shown in FIGS. 1A-1B and 2A-2B but also often present are additional components such as capacitors, resistors, coils, or inductors that can be mounted with the semiconductor dies to form a module or to form microelectronic assemblies.

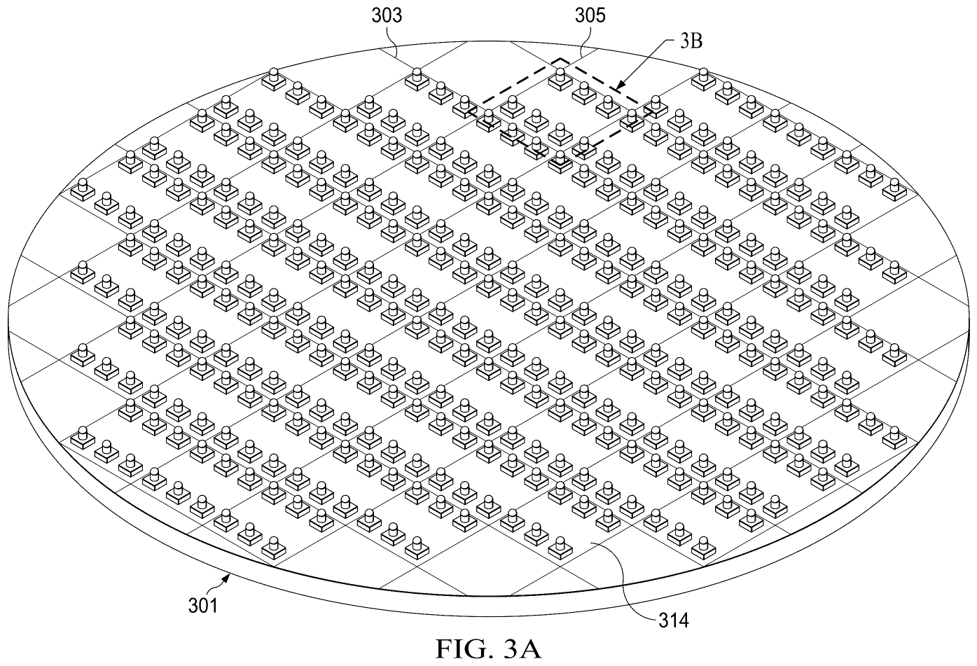

FIGS. 3A and 3B illustrate in two projection views a semiconductor wafer having semiconductor dies formed on it and configured for flip chip mounting, and an individual semiconductor die configured for flip chip mounting, respectively. In the arrangements, a semiconductor die ready for mounting can be formed using wafer bumping. In wafer bumping, after the semiconductor devices in the semiconductor substrate are completed as individual dies in a semiconductor manufacturing process, conductive post connects extending from bond pads on the semiconductor dies can be formed by a plating process. Solder can be deposited or formed on the distal ends of the conductive post connects. Various conductor materials can be used such as copper, gold, and aluminum. Copper is often used. When the conductive post connects are of copper, the term “copper pillar” is often used. When solder is applied to the distal end and then shaped as a bump shape in a thermal reflow process, the conductive post connects can be described as “copper pillar bumps.” Solder bumps can also be used.

In FIG. 3A, an example semiconductor wafer 301 is shown with an array of semiconductor dies 314 formed in rows and columns on a surface. The semiconductor dies 314 can be formed using processes in a semiconductor manufacturing facility, including ion implantation, doping, anneals, oxidation, dielectric and metal deposition, photolithography, pattern, etch, photoresist stripping, chemical mechanical polishing (CMP), electroplating, and other processes for making semiconductor devices. Scribe lanes 303 and 305, which are perpendicular to one another, and which run in parallel groups across the semiconductor wafer 301, separate the rows and columns of the completed semiconductor dies 314, and provide defined areas for dicing the wafer 301 in a singulation operation, to separate the semiconductor dies 314 from one another.

FIG. 3B illustrates a single semiconductor die 314, with bond pads 315, which are conductive pads that are electrically coupled to devices (not shown) including transistors and circuitry formed in the semiconductor die 314. Conductive post connects 316 are shown extending away from a proximate end mounted on the bond pads 315 on the surface of semiconductor die 314 to a distal end, and solder bumps 317 are formed on the distal ends of the conductive post connects 316. The conductive post connects 316 can be formed by electroless plating or electroplating. In an example, the conductive post connects 316 are copper pillar bumps. Copper pillar bumps can be formed by sputtering a seed layer over the surface of the semiconductor wafer 301, forming a photoresist layer over the seed layer, using photolithography to expose the bond pads 315 in openings in the layer of photoresist, plating the copper conductive connection posts 316 on the bond pads, and plating a lead solder or a lead-free solder such as an tin, silver (SnAg) or tin, silver, copper (SnAgCu) or “SAC” solder to form solder bumps 317 on the distal ends of the copper post connects 316. In alternative approach, solder bumps or particles may be dropped onto the distal ends of the copper post connects and then reflowed in a thermal process to form solder bumps. Other conductive materials can be used for the conductive post connects in electroplating or electroless plating operation, including gold, silver, nickel, palladium, or tin, for example. Not shown for clarity of illustration are under bump metallization (UBM) portions which can be formed over the bond pads to improve plating and adhesion between the conductive connection posts 316 and the bond pads 315. After the plating operations, the photoresist is then stripped, and the excess seed layer is etched from the surface of the wafer. The semiconductor dies 314 are then separated by dicing, or are singulated, using the scribe lanes 303, 305 (see FIG. 3A).

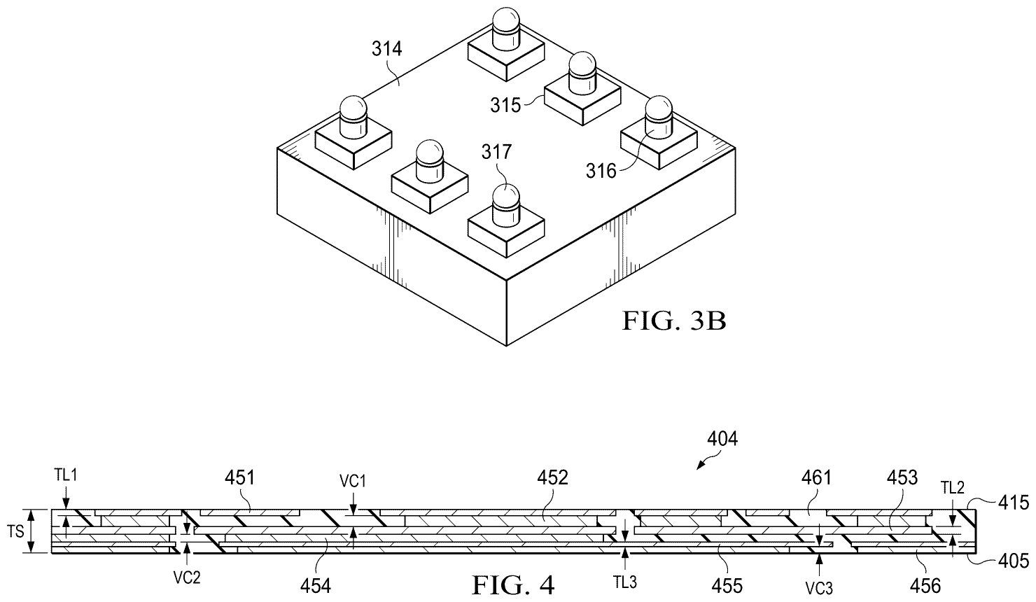

FIG. 4 illustrates in a cross-sectional view a multilayer circuit substrate 404 that can be used with the arrangements. In FIG. 4, the multilayer circuit substrate 404 has a device side surface 415 and a board side surface 405. Three trace level conductor layers 451, 453, 455 are formed spaced from one another by dielectric material 461, the trace level conductor layers are patterned for making horizontal connections, and three vertical connection layers 452, 454, 456 form electrical connections between the three trace level conductor layers 451, 453, 455 and extend through the dielectric material 461 that is disposed over and between the trace level conductor layers. The dielectric material 461 can be a build-up dielectric film such as ABF, another thermoplastic material such ASA, or can be a thermoset material, such as epoxy resin mold compound.

The circuit substrate can have various thicknesses. In one example the multilayer circuit substrate 404 has a substrate thickness labeled “TS” of about 200 μm. The various trace level conductor layers and dielectric layers between the trace level conductor layers, including the vertical connection layers, can have varying thickness as well. These thicknesses taken together can add up in total to the substrate thickness TS. In a particular example of a multilayer circuit substrate useful with the arrangements, the first trace level conductor layer, 451, near the device side surface 415 of the multilayer circuit substrate, can have a trace level conductor layer thickness TL1 of 15 μm. The first vertical connection layer, 452, can have a thickness VC1 of 25 μm. The second trace level conductor layer, 453, sometimes coupled to the first trace level conductor layer 451 by the first vertical connection layer 452, can have a thickness labeled TL2 of 60 μm. The second vertical connection layer, 454, can have a thickness labeled VC2 of 65 μm. The third trace level conductor layer, 455, can have a thickness labeled TL3 of 15 μm, and the third vertical connection layer, 456, can have a thickness labeled VC3 of 25 μm. Additional layers, such as conductive lands on the device side surface 415, or terminals on the board side surface 405, may be formed by plating (not shown in FIG. 4). A continuous vertical connection between the device side surface 415 and the board side surface 405 can be formed by patterning a stack of the trace level conductor layers and the corresponding vertical connection layers to form a continuous conductive path extending vertically through the dielectric material 461.

Note that in this description, the vertical connection layers 452, 454, and 456 are not described as “vias.” This is intentionally done in this description to distinguish the vertical connection layers of the build-up multilayer circuit substrate of the arrangements from the via connections of PCBs or other substrates, which are filled holes. The vertical connections of the arrangements can be formed using additive manufacturing, while in contrast, the vias in PCBs are usually formed by removing material, for example by via holes that are drilled into the substrate. These via holes between conductor layers then must be plated and filled with a conductor, which requires additional plating steps after the drilling steps. These additional process steps are precise manufacturing processes that add costs and require additional manufacturing tools and capabilities.

In contrast to conventional vias, the vertical connection layers used in the build-up process to form multilayer circuit substrates of the arrangements are formed in the same plating processes as those used in forming the trace level conductor layers, simplifying manufacture, and reducing costs. In addition, the vertical connection layers in the arrangements can be arbitrary shapes, such as rails, columns, or posts, and the rails can be formed in continuous patterns to form electric shields, tubs, or tanks, and can be coupled to grounds or other potentials, isolating regions of the multilayer circuit substrate from one another.

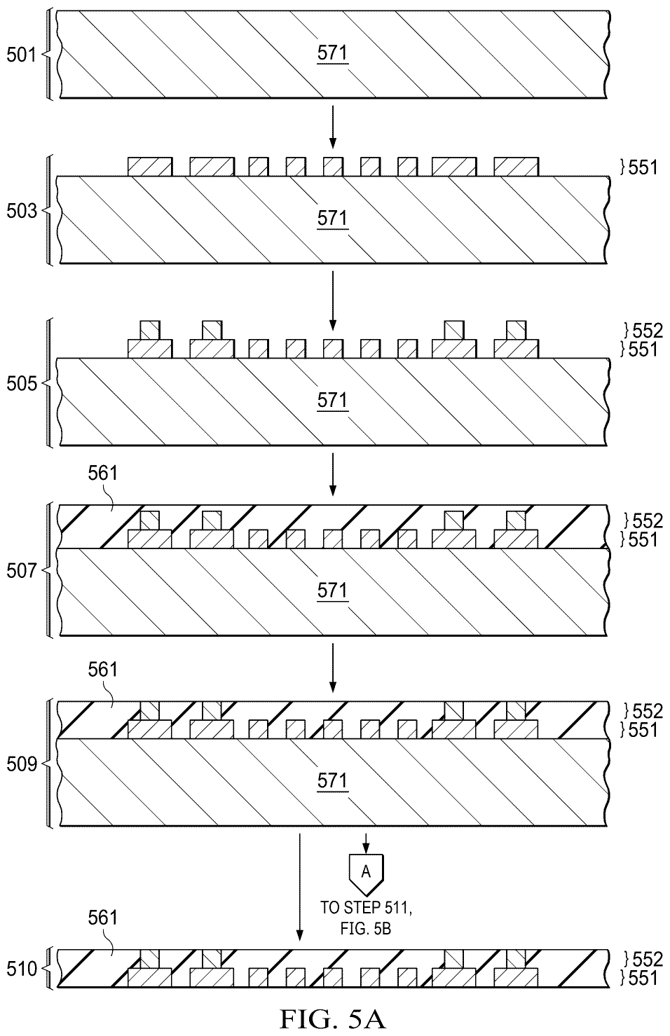

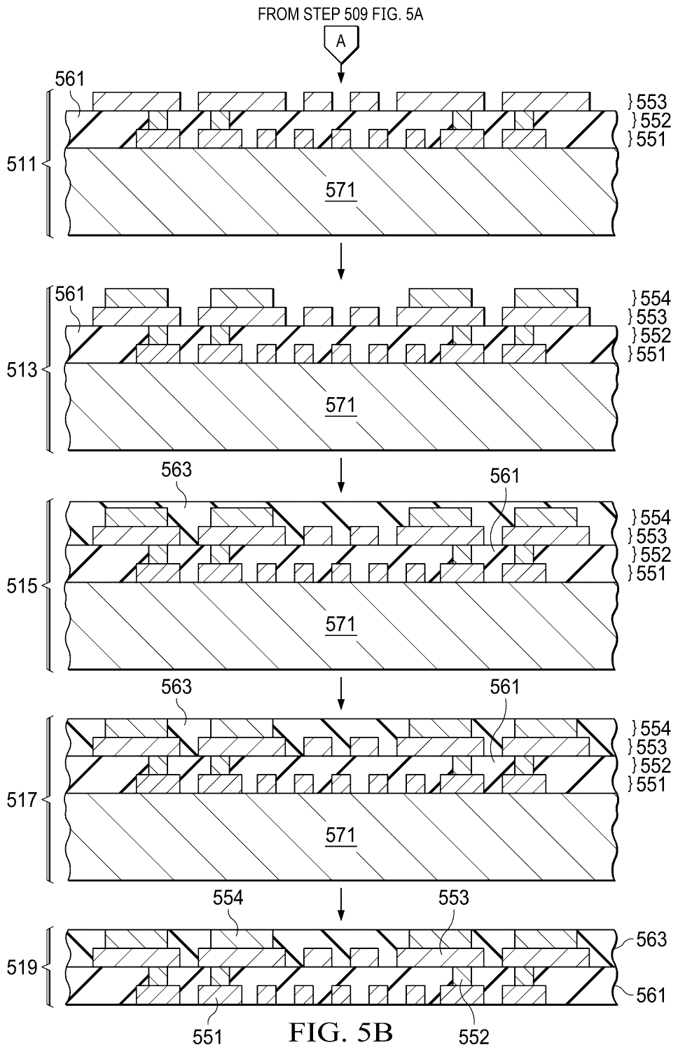

FIGS. 5A-5B (collectively “FIG. 5”) illustrate, in a series of cross-sectional views, selected steps for a method for forming a build-up multilayer circuit substrate that is useful with the arrangements. In FIG. 5A, at step 501, a metal carrier 571 is ready for a plating process. The metal carrier 571 can be stainless steel, steel, aluminum, or another metal that will support the multilayer circuit substrate layers during plating and molding steps, the multilayer circuit substrate is then removed, and the metal carrier is cleaned for additional manufacturing processes.

At step 503, a first trace level conductor layer 551 is formed by plating. In an example process, a seed layer is deposited over the surface of metal carrier 571, by sputtering, chemical vapor deposition (CVD) or other deposition step. A photoresist layer is deposited over the seed layer, exposed, developed, and cured to form a pattern to be plated. Electroless or electroplating is performed using the exposed portions of the seed layer to start the plating, forming a pattern according to patterns in the photoresist layer.

At step 505, the plating process continues. A second photoresist layer is deposited, exposed, and developed to pattern the first vertical connection layer 552. In this example process, the process is simplified by leaving the first photoresist layer in place, the second photoresist layer is used without an intervening strip and clean step. The first trace level conductor layer 551 can be used as a seed layer for the second plating operation, to further simplify processing. However, in an alternative process, a seed layer can be deposited for each conductive layer, and plating can be performed using each successive seed layer.

At step 507, a dielectric layer is formed. The first trace level conductor layer 551 and the first vertical connection layer 552 are covered in a dielectric material. In an example using ABF, the dielectric is provided as a film. The film is warmed to make it conformal, and stretched over layers 551, 552. A vacuum process can be used to cause the film to conform to the shapes of the conductors without voids. A curing process then hardens the film into a solid dielectric material. In alternative further examples ASA can be used, or a thermoset epoxy resin mold compound can be used, or resins, epoxies, or plastics can be used. In an example compressive molding operation, a mold compound can be heated to a liquid state, forced under pressure through runners into a mold to cover the first trace level conductor layer 551 and the first vertical connection layer 552, and subsequently cured to form solid mold compound for the dielectric material 561.

At step 509, a grinding operation is performed on the surface of the dielectric material 561 and exposes a surface of the first vertical connection layer 552 and provides conductive surfaces for mounting devices, or for use in additional plating operations. If the multilayer circuit substrate is complete, the method ends at step 510, where a de-carrier operation removes the metal carrier 571 from the dielectric material 561, leaving the first trace level conductor layer 551 and the first vertical connection layer 552 in a dielectric material 561, providing a circuit substrate.

In examples where additional trace level conductor layers and additional vertical connection layers are needed, the method continues, leaving step 509 and transitioning to step 511 in FIG. 5B.

At step 511, a second trace level conductor layer 553 is formed by plating using the same processes as described above with respect to step 505. A seed layer for the plating operation is deposited and a photoresist layer is deposited and patterned, and the plating operation forms the second trace level conductor layer 553 over dielectric material 561, with portions of the second trace level conductor layer 553 electrically connected to the first vertical connection layer 552.

At step 513, a second vertical connection layer 554 is formed using an additional plating step on the second trace level conductor layer 553. The second vertical connection layer 554 can be plated using the second trace level conductor layer 553 as a seed layer, and without the need for removing the preceding photoresist layer, simplifying the process. Alternatively, each successive layer can be formed using a seed layer and photolithography to pattern the plated layers.

At step 515, a second dielectric deposition is performed to cover the second trace level conductor layer 553 and the second vertical connection layer 554 in a layer of dielectric material 563. The dielectric film deposition, vacuum, and cure steps are again performed as described above. The multilayer circuit substrate at this stage has a first trace level conductor layer 551, a first vertical connection layer 552, a second trace level conductor layer 553, and a second vertical connection layer 554, portions of the layers are electrically connected to form vertical paths through the layers of dielectric material 561 and 563.

At step 517, the dielectric material 563 is mechanically ground in a grinding process or chemically etched to expose a surface of the second vertical connection layer 554.

At step 519 the example method ends by removing the metal carrier 571, leaving a build-up circuit substrate including the trace level conductor layers 551, 552, 553 and 554 in dielectric material 561, 563. The steps of FIGS. 5A-5B can be repeated to form multilayer circuit substrates for use with the arrangements having more layers, by performing plating of a trace level conductor layer, plating of a vertical connection layer, applying dielectric firm or molding a dielectric layer, and grinding, repeatedly.

In forming the conductive stud bumps used in the arrangements, additional plating is performed over the circuit substrate 5B to form conductive stud bumps or conductive rails arranged for mounting a passive component to the device side surface of the circuit substrate. Use of the conductive stud bumps in the arrangements eliminates the need for the conductive clips used to mount passive components to the substrate in a prior approach. In addition, the need for assembly steps to mount conductive clips to the circuit substrate are eliminated. Because the conductive stud bumps are formed as plated conductors on the circuit substrate using conventional plating and etch processes, there is no need to solder or otherwise adhesively mount discrete clip portions to the circuit substrate, saving time in the assembly process and reducing costs.

In example arrangements, a semiconductor die can be combined with passive components, for example an inductor, and mounted to a device mounting surface of a multilayer circuit substrate. In forming the arrangements, the semiconductor dies, and the passive components, can be formed independently of the circuit substrate, so that methods for forming the semiconductor die, the passive components and the circuit substrate can be performed at various times, and at various facilities or locations. The components can then be assembled to complete the arrangements. In an example arrangement, a multilayer circuit substrate includes conductive studs formed on the device side surface that are configured for mounting inductors (or, in alternative arrangements, other passive components). After flip-chip mounting the semiconductor die to the circuit substrate, mold compound is deposited and covers portions of the semiconductor die and the conductive stud bumps. The mold compound can be opened to expose the surface of the conductive studs in a trench. In an example process useful with the arrangements, a saw is used to make a partial cut into the mold compound to open a trench extending into the mold compound that exposes a surface of the conductive stud bumps. Inductors (as an example, other passives can be mounted) can be mounted to the conductive stud bumps. In an example arrangement, the inductor or other passive component is positioned to be in thermal contact with an exposed backside surface of the semiconductor die, to enhance the thermal dissipation of the assembled devices. Additional components such as capacitors and resistors can also be mounted to the multilayer circuit substrate. Optionally, a housing can be formed around the elements to provide protection for the module. The multilayer circuit substrate can have terminals on a board side surface for mounting the module or for making electrical connections to a system.

The passive components, for example inductors, can have terminals that are shaped as extended rails or feet that correspond to, and which are configured for mounting to the conductive stud bumps. In an example mounting process used in forming an arrangement, terminals of the passive component are inserted into the trenches in the mold compound and contact an exposed surface of the conductive stud bumps, and the trenches can provide additional mechanical support. Inductors useful with the arrangements can further include a thermally conductive band of material on an exterior portion that is placed in thermal contact with the backside surface of the semiconductor die, and which acts as a heat sink or thermal dissipation path.

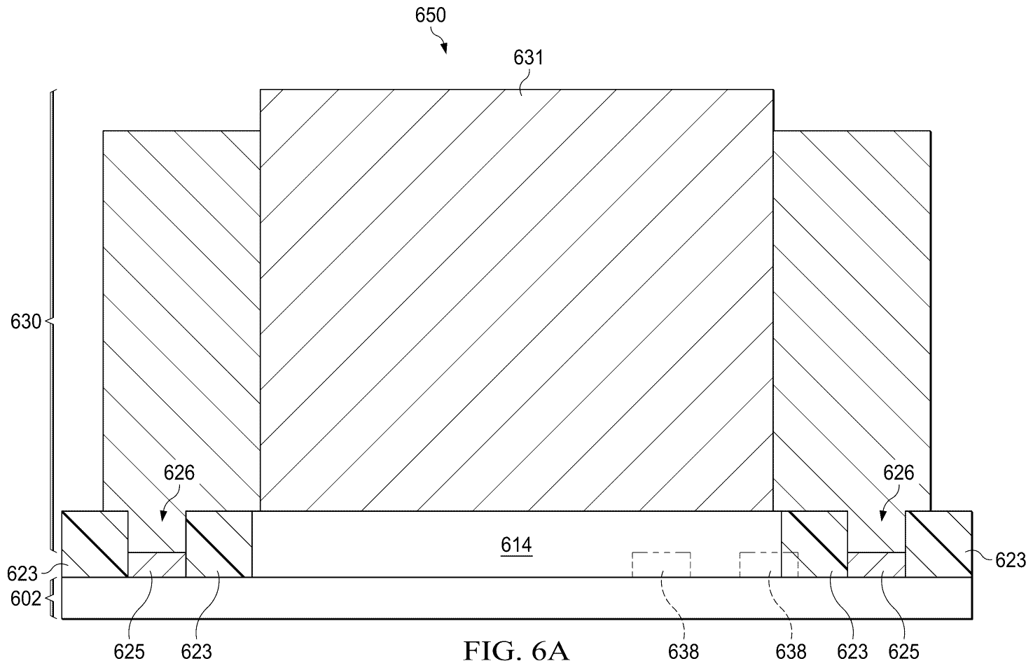

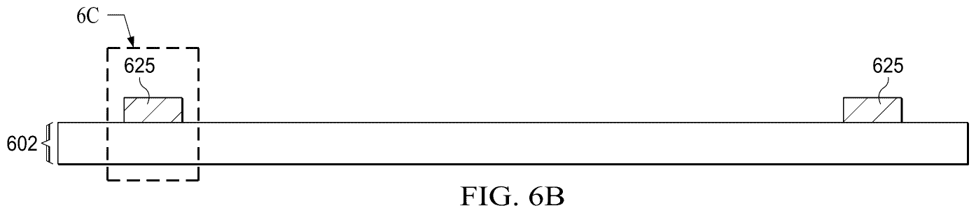

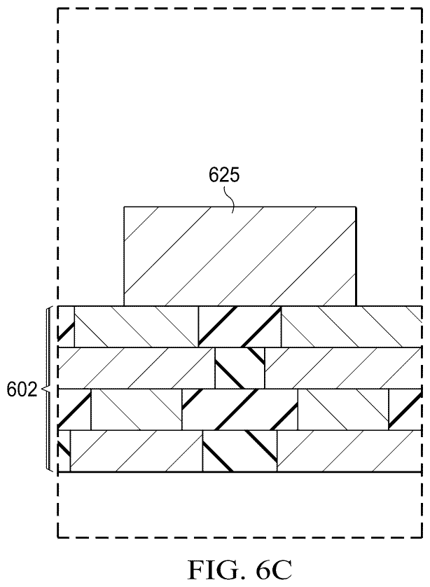

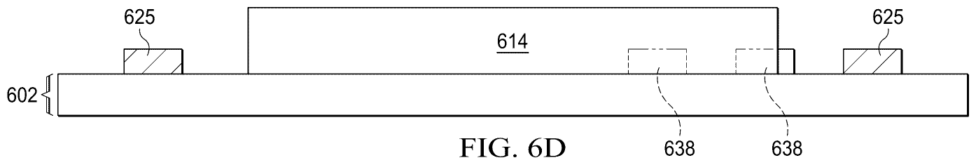

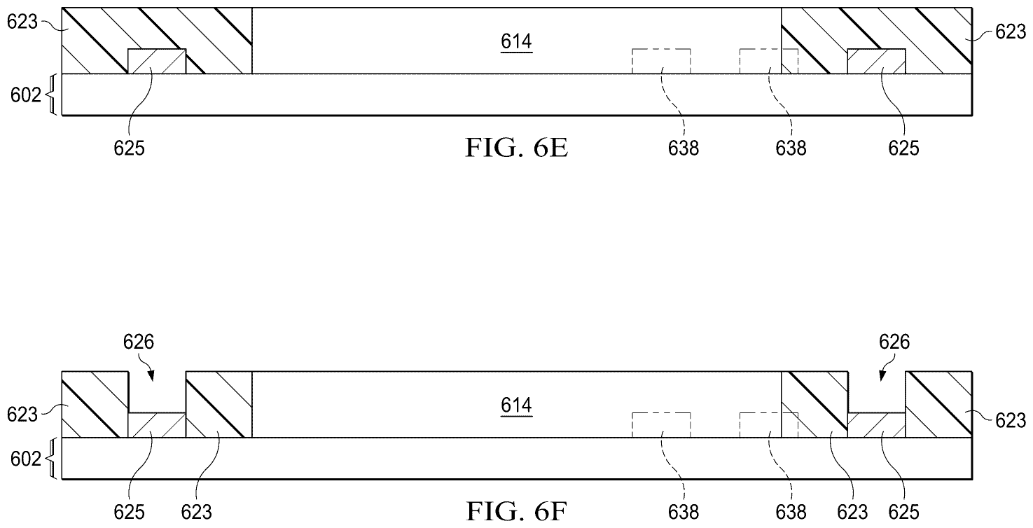

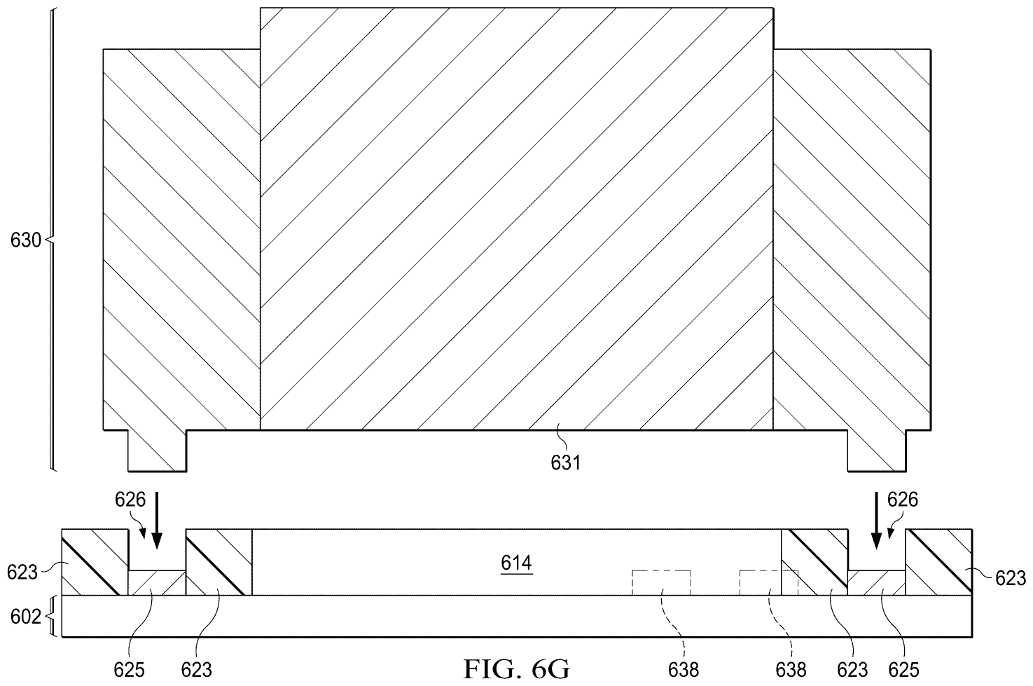

FIG. 6A illustrates, in a cross-sectional view, an example arrangement for a microelectronic assembly including a semiconductor die and an inductor mounted to a multilayer circuit substrate. In FIG. 6A, the microelectronic assembly 650 is shown with a multilayer circuit substrate 602, which corresponds to and is similar to the multilayer circuit substrate 404 in FIG. 4. In a particular example, the processes shown in FIGS. 5A-5B can be used to form the multilayer circuit substrate as a build-up substrate. In a particular example, the multilayer circuit substrate can be formed using Ajinomoto Build-Up Film (ABF), and additive plating processes as described above. However, in alternative arrangements, other multilayer circuit board technologies can be used with the arrangements.

In FIG. 6A, microelectronic assembly 650 includes an inductor 630 that is mounted to the multilayer circuit substrate 602. A semiconductor die 614 is flip chip mounted to the multilayer circuit substrate 602. Mold compound 623 is deposited on a portion of the multilayer circuit substrate 602 and protects parts of the semiconductor die 614 and the flip-chip connections between the semiconductor die 614 (not visible in the cross-section). The mold compound 623 also surrounds portions of the conductive stud bumps 625, while trenches are opened to expose surfaces of the conductive stud bumps 625 for mounting. The inductor 630 is mounted to conductive stud bumps 625 (which extend into the page and can be shaped as rectangular rails extending to a length much greater than a width shown in the cross-section). The inductor 630 has terminals or feet for mounting that are shaped and configured to enable mounting to the conductive stud bumps 625. In example arrangement 650, a thermal band of a thermally conductive material is formed and covers a portion of the exterior of the inductor 630 and is positioned to cover and contact the exposed backside of the semiconductor die 614.

FIGS. 6B-6G illustrate, in a series of cross-sectional views, selected steps for forming an example arrangement.

FIG. 6B illustrates conductive stud bumps 625 formed on the device side surface of the multilayer circuit substrate 602. In an example process that is useful with the arrangements, a metal deposition process can deposit a layer of conductive material over the device side surface of the circuit substrate 602. The layer of conductive material can then be patterned in a photolithographic process. A layer of resist material can be deposited over the conductive material, and using photolithographic masks, a pattern can be formed. Metal etch processes can be used to remove excess conductive layer and form the conductive stud bumps. The conductive stud bumps can be shaped as a rail or rectangle, can be other shapes such as squares, can be a single piece of conductor or can be formed in multiple pieces, for example in pairs, and are arranged to be used in mounting a passive component.

In an example arrangement, the conductive stud bumps can be of copper or a copper alloy. Alternatively conductive material such as gold, silver or aluminum can be used.

FIG. 6C illustrates in a cross-sectional view a close-up of a conductive stud bump 625 formed using copper deposition in an example process on a multilayer circuit substrate 602.

FIG. 6D illustrates, in a cross-sectional view, the elements of FIG. 6A after a component mounting step. A semiconductor die 614 is shown after a flip-chip mounting step. The semiconductor die 614 can be a power semiconductor die such as a switching power device and can include a power FET for delivering current into an inductor or transformer, for example, and can include additional associated circuitry such as a gate driver device and a switching controller that implements a switching power device. For example, a pulse width modulated switching power device can be implemented on semiconductor die 614. Additional passive components useful for forming a complete circuit function can also be mounted to the device side surface of the circuit substrate 602. In FIG. 6D, capacitors 638 are shown. The conductive stud bumps 625 are positioned on either end of the semiconductor die 614 and are spaced from the semiconductor die 614.

FIG. 6E illustrates, in another cross-sectional view, the elements of FIG. 6D after a molding process forms mold compound 623. As shown in FIG. 6E, mold compound 623 is formed over a portion of the device side surface of the circuit substrate 602. The mold compound 623 covers the conductive stud bumps 625 and covers portions of the semiconductor die 614, while a backside surface of the semiconductor die 614 remains exposed from the mold compound 623. Because the mold compound 623 is formed only on the device side of the circuit substrate 602, this may be described as an “overmolding” process. The mold compound can form a ring around the semiconductor die to protect the sides of the semiconductor die 614. In a process useful with the arrangements, film assisted transfer or compression molding can be used with a thermoset mold compound to form mold compound 623. A thermoset mold compound can be an epoxy resin mold compound that is a solid at room temperature. In a transfer molding process, a solid puck or a powdered mold compound is heated in a chamber to a liquid state. Hydraulic pressure can be applied to the liquid mold compound to force it through runners into mold cavities. The mold compound covers a portion of the device side surface of circuit substrate 602, which is placed in the mold. In a film assisted molding process, some portions of the devices where the mold compound is not to be deposited are protected by a film, which is removed from the devices after molding. The mold compound is allowed to set, and an additional curing step can be used to harden the mold compound into a solid plastic.

FIG. 6F illustrates, in a further cross-sectional view, the elements of FIG. 6E, after a partial cut process is performed. In FIG. 6F, the conductive stud bumps 625 are shown exposed in trenches formed in the mold compound 623 by a partial cut operation that cuts trenches 626 into the mold compound to expose a surface of the conductive stud bumps 625. In a useful process, a saw such as used for singulation is used in a partial cutting process to cut into the mold compound to a depth to expose the conductive stud bumps 625, leaving a trench extending into the mold compound with the conductive stud bumps exposed in the trench.

FIG. 6G illustrates, in a further cross-sectional view, the elements of FIG. 6F in a passive component mounting process. In FIG. 6G, an inductor 630, or alternatively another passive component, is shown being mounted to the multilayer circuit substrate 602. Inductor 630 has terminals 631 that are configured to be installed by inserting the terminals into the trenches 626 in the mold compound 623 and mounted using solder to mount the passive component (here inductor 630) to the conductive stud bumps 625. The passive component (inductor 630) is then electrically coupled to traces in the circuit substrate 602 and may be coupled to the semiconductor die 614 by traces in or on the device side of the circuit substrate 602.

In the example arrangements, the passive component (inductor 630 in the illustrations) is positioned over semiconductor die 614, which integrates the elements in the same area of the circuit substrate 602, increasing the density of components in the substrate area. In addition, in the example arrangements, the passive component, here and inductor 630, has a thermal band 631 surrounding a portion of the exterior of the passive component. The passive component (inductor 630 in the illustrations) is positioned in thermal contact with the backside surface of the semiconductor die 614, providing a thermal dissipation path to transfer heat away from the semiconductor die 614 while in operation.

The process is completed by forming the example arrangement shown in FIG. 6A, a microelectronic assembly 650 including the inductor 630 mounted with the semiconductor die 614 to the circuit substrate 602. In the arrangements, the conductive stud bumps eliminate the need for the clips used to mount the passive component on the circuit substrate used in prior approaches. The need for separate steps to mount the clips and couple the clips to the circuit substrate, and then to subsequently mount the passive component to the clips, eliminates the need to manufacture and use the discrete clips and the assembly steps related to the clips, reducing costs, and increasing reliability.

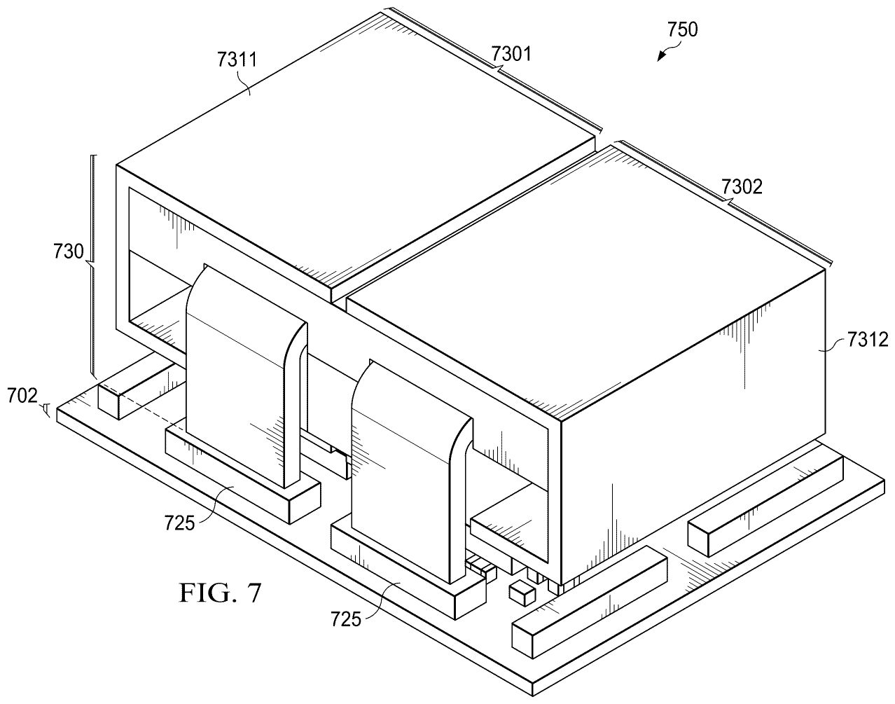

FIG. 7 illustrates, in a projection view, a microelectronic assembly 750 formed using example arrangements. In FIG. 7, a pair of inductors 7311 and 7312, which can be similar or in some applications can be identical, are shown mounted to conductive stud bumps 725 using the methods described above. The inductors have C-shaped thermal bands 7311, 7312 and in addition, below the inductors 7311, 7312 are semiconductor dies flip-chip mounted to the circuit substrate 702, as described above, that are also electrically coupled to the inductors using conductive traces in the circuit substrate 702. Microelectronic assembly 750 implements a voltage regulator function. Other circuitry requiring relatively large passive devices and semiconductor dies can be formed in alternative arrangements using the mold compound and conductive stud bumps to mount the passive components over the semiconductor dies as shown in FIG. 6A for example, to increase integration and provide a thermal dissipation path, without the use of the mounting clips of the prior approach assembly methods.

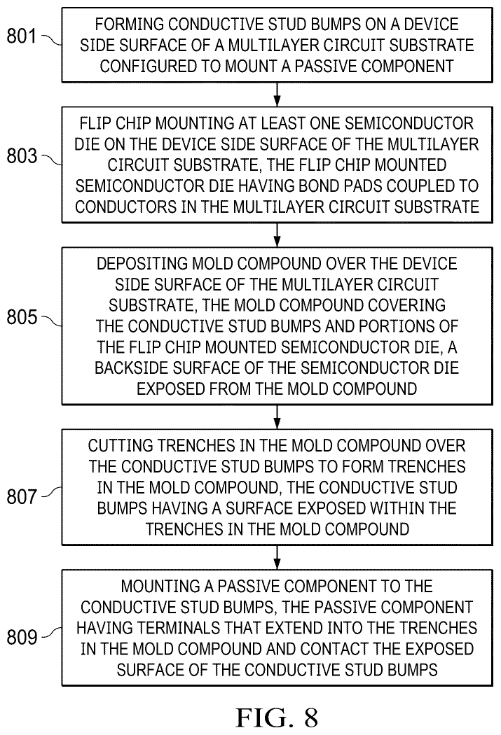

FIG. 8 is a process flow diagram of an example process for forming an arrangement. The process begins at step 801, by forming conductive stud bumps on a device side surface of a multilayer circuit substrate configured to mount a passive component. (See, for example, FIG. 6B, where the conductive stud bumps 625 are shown on multilayer circuit substrate 602, and FIG. 6C, a close-up view of the conductive stud bump 625). The method continues at step 803 in FIG. 8, by flip chip mounting at least one semiconductor die on the device side surface of the multilayer circuit substrate, the flip chip mounted semiconductor die having bond pads coupled to conductors in the multilayer circuit substrate; (see, for example, FIG. 6D, where the semiconductor die 614 is shown flip-chip mounted to the multilayer circuit substrate 602).

The method continues at step 805 in FIG. 8, where mold compound is deposited over the device side surface of the multilayer circuit substrate, the mold compound covering the conductive stud bumps and portions of the flip chip mounted semiconductor die, a backside surface of the semiconductor die exposed from the mold compound. (See, for example, FIG. 6E showing mold compound 623 formed over the conductive stud bumps 625, while the semiconductor die 614 has a backside exposed from the mold compound 623.)

At step 807 in FIG. 8, the method continues by cutting into the mold compound over the conductive stud bumps to form trenches in the mold compound, the conductive stud bumps having a surface exposed within the trenches in the mold compound. (See, for example, FIG. 6F, where trenches 626 are shown formed in mold compound 623 to expose the conductive stud bumps 625 in trenches 626. A saw blade arranged for a partial cut can be used to cut through the mold compound and expose the conductive stud bumps 625).

At step 809 the method continues by mounting a passive component to the conductive stud bumps, the passive component having terminals that extend into the trenches in the mold compound, and which contact the exposed surface of the conductive stud bumps. (See, for example, FIG. 6G where the inductor 630, a passive component, is shown being mounted to the conductive stud bumps 625 in the trenches in the mold compound 623). A solder reflow process can be used to attach the terminals of the passive component to the conductive stud bumps.

In the methods used to form the arrangements, the multilayer circuit substrate can be formed independently from the semiconductor dies and the passive components, and various vendors or facilities can be used to provide these components for assembly. The multilayer circuit substrate can be formed using additive manufacturing such as using Ajinomoto build-up film in a series of plating and lamination steps to form multiple conductor layers spaced by ABF. Other circuit substrates can be used. The conductive stud bumps can be formed over the multilayer circuit substrate using a deposition and etch process. Alternatively, a seed layer can be deposited, covered by patterned photoresist, and plating can be used to form the conductive stud bumps. Various tools and processes used for packaging and circuit board assembly such as flip chip mounting, transfer molding, film assisted molding, and singulation saws can be used to perform the steps to form the arrangements. Because the use of the conductive stud bumps by deposition of the conductive stud bumps eliminates the need for manufacturing and mounting discrete clips for mounting the passive components, the use of the arrangements simplifies the assembly process and reduce the number of parts, reducing costs.

Modifications are possible in the described examples, and other examples are possible, within the scope of the claims.

What is claimed is:

1. A method, comprising:
forming conductive stud bumps on a device side surface of a multilayer circuit substrate configured to mount a passive component;
flip chip mounting at least one semiconductor die on the device side surface of the multilayer circuit substrate, the flip chip mounted semiconductor die having bond pads coupled to conductors in the multilayer circuit substrate;
depositing mold compound over the device side surface of the multilayer circuit substrate, the mold compound covering the conductive stud bumps and portions of the flip chip mounted semiconductor die, a backside surface of the semiconductor die exposed from the mold compound;
cutting trenches in the mold compound over the conductive stud bumps to form trenches in the mold compound, the conductive stud bumps having a surface exposed within the trenches in the mold compound; and
mounting a passive component to the conductive stud bumps, the passive component having terminals that extend into the trenches in the mold compound and contact the exposed surface of the conductive stud bumps.

2. The method of claim 1, wherein the passive component further comprises a thermal band that surrounds a portion of an exterior surface of the passive component and the thermal band is in thermal contact with the exposed backside surface of the semiconductor die.

3. The method of claim 1, wherein forming conductive stud bumps further comprises:
depositing a layer of conductor material over the device side surface of the multilayer circuit substrate; and
patterning the layer of conductor material using photolithography and etch processes to form the conductive stud bumps.

4. The method of claim 1, wherein forming conductive stud bumps further comprises forming the conductive stud bumps with a rail shape.

5. The method of claim 3, wherein depositing a layer of conductor material further comprises depositing copper or a copper alloy.

6. The method of claim 1, wherein depositing mold compound further comprises using epoxy mold compound in a film assisted molding process to form mold compound covering the sides of the semiconductor die and the conductive stud bumps, while the backside of the semiconductor die remains exposed from the mold compound.

7. The method of claim 1, wherein mounting the passive component further comprises mounting an inductor, a coil, a transformer, a capacitor, or a resistor.

8. The method of claim 1, wherein mounting the passive component further comprises mounting an inductor.

9. The method of claim 1, wherein mounting at least one semiconductor die comprises mounting a first semiconductor die, and further comprising flip chip mounting a second semiconductor die to the device side surface of the multilayer circuit substrate.

10. The method of claim 9, wherein mounting the passive component comprises mounting a first inductor over the first semiconductor die, and further comprising mounting a second inductor over the second semiconductor die.

11. The method of claim 10, wherein forming the conductive stud bumps comprises forming a first pair of conductive stud bumps configured for mounting the first inductor, and further comprises forming a second pair of conductive stud bumps configured for mounting the second semiconductor die.

12. An apparatus, comprising:
conductive stud bumps on a device side surface of a multilayer circuit substrate configured to mount a passive component;
at least one semiconductor die flip-chip mounted to the device side surface of the multilayer circuit substrate, the at least one semiconductor die having bond pads coupled to conductors in the multilayer circuit substrate;
mold compound deposited over the device side surface of the multilayer circuit substrate, the mold compound covering a portion of the semiconductor die and having a trench extending into the mold compound that exposes the conductive stud bumps; and
a passive component mounted to the conductive stud bumps, the passive component having terminals that extend into the trenches in the mold compound and contact a surface of the conductive stud bumps.

13. The apparatus of claim 12, wherein the passive component further comprises a thermal band that surrounds a portion of an exterior surface of the passive component, and wherein the thermal band is in thermal contact with a portion of the backside surface of the semiconductor die.

14. The apparatus of claim 12, wherein the conductive stud bumps are formed of copper or copper alloy.

15. The apparatus of claim 12, wherein the conductive stud bumps comprise a first conductive stud bump positioned spaced from one end of the semiconductor die and a second conductive stud bump positioned spaced from an opposite end of the semiconductor die.

16. The apparatus of claim 15, wherein the passive component has a first terminal mounted to the first conductive stud bump, and a second terminal mounted to the second conductive stud bump, and the passive component lies over at least a portion of the backside of the semiconductor die.

17. The apparatus of claim 12, wherein the passive component is an inductor, a coil, a transformer, a capacitor, a diode, or a sensor.

18. The apparatus of claim 12, wherein the at least one semiconductor die is a first semiconductor die, and further comprising a second semiconductor die that is flip chip mounted to the device side surface of the multilayer circuit substrate, the second semiconductor die spaced from the first semiconductor die.

19. The apparatus of claim 18, wherein the passive component is a first passive component, and further comprising a second passive component mounted to conductive stud bumps on the multilayer circuit substrate, and the second passive component has an additional thermal band that surrounds a portion of an exterior surface of the second passive component, and the additional thermal band is in thermal contact with a backside surface of the second semiconductor die.

20. The apparatus of claim 19, wherein the first passive component and the second passive component are both inductors.

21. A microelectronic assembly, comprising:
a multilayer circuit substrate having conductive stud bumps on a device side surface configured to mount a passive component;
at least one semiconductor die flip-chip mounted to the device side surface of the circuit substrate, a first one of the conductive stud bumps spaced from a first end of the semiconductor die, and a second one of the conductive stud bumps spaced from a second end of the semiconductor die;
mold compound deposited over a portion of the at least one semiconductor die, and trenches in the mold compound exposing a surface of the conductive stud bumps, the at least one semiconductor die having a backside surface exposed from the mold compound; and
a passive component having terminals mounted to the conductive stud bumps, the passive component positioned over a portion of a backside surface of the at least one semiconductor die.
